(19) United States
(12) Patent Application Publication
(10) Pub. No.: US 2013/0094166 A1
(43) Pub. Date: Apr. 18, 2013

(54) DISPLAY APPARATUS

(71) Applicants: Makoto Yokoyama, Osaka-shi (JP); Eiji Matsuda, Osaka-shi (JP); Takahiro Yamaguchi, Osaka-shi (JP); Shuji Nishi, Osaka-shi (JP); Takuya Hachida, Osaka-shi (JP); Seijirou Gyouten, Osaka-shi (JP)

(72) Inventors: Makoto Yokoyama, Osaka-shi (JP); Eiji Matsuda, Osaka-shi (JP); Takahiro Yamaguchi, Osaka-shi (JP); Shuji Nishi, Osaka-shi (JP); Takuya Hachida, Osaka-shi (JP); Seijirou Gyouten, Osaka-shi (JP)

(21) Appl. No.: 13/701,541

(22) PCT Filed: May 11, 2011
(86) PCT No.: PCT/JP2011/060882

§ 371 Date: Dec. 3, 2012

(30) Foreign Application Priority Data
Jun. 30, 2010 (JP) 2010-150283

(51) Int. Cl. H05K 7/02

(52) U.S. Cl. CPC H05K 7/026
USPC 361/784; 361/748

(57) ABSTRACT

A plurality of display panels (10A and 10B) are provided on a single substrate (2). Data signal lines (11A), scanning signal lines (12A), a data signal line drive circuit (20A) for driving the data signal lines (11A), and a scanning signal line drive circuit (30A) for driving the scanning signal lines (12A) are provided for the display panel (10A). Data signal lines (11B), scanning signal lines (12B), a data signal line drive circuit (20B) for driving the data signal lines (11B), and a scanning signal line drive circuit (30B) for driving the scanning signal lines (12B) are provided for the display panel (10B). Input signal lines (17A and 17B) are provided so as not intersect each other in a plan view. This allows a reduction in power consumption and an increase in flexibility in design in a display panel which includes a plurality of display panels on a single substrate.

### TECHNICAL FIELD

The present invention relates to a display device including a plurality of display panels.

### BACKGROUND ART

Conventionally, for the purpose of reducing a size and a weight of an electronics device such as a cell-phone, there has been proposed a technique of providing a plurality of display panels on a single substrate (Patent Literature 1, etc.).

FIG. 17 is a plan view illustrating a configuration of a liquid crystal display device described in Patent Literature 1. The liquid crystal display device includes a first display panel (main panel 130) and a second display panel (sub-panel 140), which are provided in respective different regions on a glass substrate 120. The liquid crystal display device also includes a drain wire (data signal line), a source driver (data signal line drive circuit), a gate driver (scanning signal line drive circuit), and the like, each of which is shared by the main panel 130 and the sub-panel 140.

The configuration makes it possible to cause the main panel 130 and the sub panel 140 to display respective different images. The configuration also makes it possible to reduce a size of a liquid crystal display device and a size of an electronics device including the liquid crystal display device.

### CITATION LIST

### Patent Literature

Patent Literature 1

Japanese Patent Application Publication, Tokukai, No. 2004-70218 A (Publication Date: Mar. 4, 2004)

### SUMMARY OF INVENTION

### Technical Problem

However, a conventional technique as described above has a problem that since the gate driver is shared between the main panel 130 and the sub-panel 140, electricity is wasted.

For example, even in a case where an image is displayed only on the main panel 130 and nothing is displayed on the sub-panel 140, shift resisters which constitute the gate driver are sequentially caused to operate, so that electricity consumed for operations of shift resisters corresponding to the sub-panel 140 is wasted.

Further, the source driver and the drain wire are also shared between the main panel 130 and the sub-panel 140. As such, for example, the main panel 130 and the sub-panel 140 cannot be driven by respective different driving methods. This reduces flexibility in design.

The present invention is accomplished in view of the problems. An object of the present invention is to reduce electric power consumption and increase flexibility in design in a display device in which a plurality of display panels are provided on a single substrate.

### Solution to Problem

In order to attain the object, a display device in accordance with the present invention is a display device including: a substrate; a plurality of display panels provided on the substrate; a plurality of input signal lines for supplying, to the plurality of display panels, an input signal which has been externally supplied, the plurality of input signal lines being provided on the substrate; a plurality of data signal lines provided for each of the plurality of display panels; a plurality of scanning signal lines provided for each of the plurality of display panels; a data signal line drive circuit for driving the plurality of data signal lines, the data signal line drive circuit being provided for each of the plurality of display panels; and a scanning signal line drive circuit for driving the plurality of scanning signal lines, the scanning signal line drive circuit being provided for each of the plurality of display panels, the plurality of input signal lines being arranged so as not to intersect each other in a plan view.

According to the configuration, display panels are provided in respective different regions on a single substrate, and drive circuits and signal lines are provided for each of the display panels. This allows each of the display panels to be driven independently. For example, in a case where two display panels A and B are provided, it is possible to control driving in accordance with a situation in which the display device is used. For example, it is possible to (1) drive both the display panels A and B, (2) drive the display panel A and stop driving the display panel B, (3) stop driving the display panel A and drive the display panel B, or (4) stop driving the display panels A and B. This makes it possible to reduce electric power consumption and increase flexibility in design.

Further, according to the configuration, it is possible to reduce an influence of cross talk between an input signal line corresponding to the display panel A and an input signal line corresponding to the display panel B. The configuration is therefore particularly suitable for a case in which the display panels A and B are driven in respective different manners.

### Advantageous Effects of Invention

As described above, a display device in accordance with the present invention includes a substrate; a plurality of display panels provided on the substrate; a plurality of input signal lines for supplying, to the plurality of display panels, an input signal which has been externally supplied, the plurality of input signal lines being provided on the substrate; a plurality of data signal lines provided for each of the plurality of display panels; a plurality of scanning signal lines provided for each of the plurality of display panels; a data signal line drive circuit for driving the plurality of data signal lines, the data signal line drive circuit being provided for each of the plurality of display panels; and a scanning signal line drive circuit for driving the plurality of scanning signal lines, the scanning signal line drive circuit being provided for each of the plurality of display panels, the plurality of input signal lines being arranged so as not to intersect each other in a plan view.

This makes it possible to reduce power consumption and increase flexibility in design in a display panel in which a plurality of display panels are provided on a single substrate.

### BRIEF DESCRIPTION OF DRAWINGS

FIG. 1

FIG. 1 is a block diagram illustrating an entire configuration of a liquid crystal display device in accordance with Embodiment 1.

FIG. 2

(a) of FIG. 2 is an equivalent circuit diagram illustrating an electric configuration of one pixel of a display panel 10A in a liquid crystal display device of Embodiment 1. (b) of FIG. 2 is an equivalent circuit diagram illustrating an electric configuration of one pixel of a display panel 10B in the liquid crystal display device of Embodiment 1.

FIG. 3

(a) of FIG. 3 is a timing diagram of an input signal in a display panel 10A. (b) of FIG. 3 is a timing diagram of an input signal in a display panel 10B.

FIG. 4

(a) of FIG. 4 is a view showing a range of a power supply voltage in a display panel 10A. (b) of FIG. 4 is a view showing a range of a power supply voltage in a display panel 10B.

FIG. 5

FIG. 5 is a schematic cross-sectional view taken along arrow X-Y in FIG. 1.

FIG. 6

FIG. 6 is a block diagram illustrating a method driving a liquid crystal display device of Embodiment 1.

FIG. 7

FIG. 7 is an equivalent circuit diagram partially showing display panels 10A and 10B of a liquid crystal display panel in accordance with Configuration Example 1.

FIG. 8

FIG. 8 is an equivalent circuit diagram partially showing display panels 10A and 10B of a liquid crystal display panel in accordance with Configuration Example 2.

FIG. 9

FIG. 9 is an equivalent circuit diagram partially showing display panels 10A and 10B of a liquid crystal display panel in accordance with Configuration Example 3.

FIG. 10

FIG. 10 is a block diagram showing an entire configuration of a liquid crystal display device of Embodiment 2.

FIG. 11

FIG. 11 is a schematic cross-sectional view taken along arrow X-Y in FIG. 9.

FIG. 12

(a) of FIG. 12 is a view showing (i) a wave form (counter DC driving) of a voltage supplied to a counter electrode 16A and (ii) a wave form (counter AC driving) of a voltage supplied to a counter electrode 16B in a liquid crystal display device of Embodiment 2. (b) of FIG. 12 is a view showing (i) a wave form (counter AC driving) of a voltage supplied to the counter electrode 16A and (ii) a wave form (counter AC driving) of a voltage supplied to the counter electrode 16B of the liquid crystal display device of Embodiment 2.

FIG. 13

FIG. 13 is a block diagram illustrating an entire configuration of a liquid crystal display device in accordance with Configuration Example 4.

FIG. 14

FIG. 14 is a block diagram illustrating an entire configuration of a liquid crystal display device in accordance with the Configuration Example 5.

FIG. 15

FIG. 15 is a block diagram illustrating an entire configuration of a liquid crystal display device in accordance with Configuration Example 6.

FIG. 16 is a block diagram illustrating an entire configuration of a liquid crystal display device in accordance with Configuration Example 7.

FIG. 17

FIG. 17 is a block diagram illustrating a configuration of a conventional display device.

### DESCRIPTION OF EMBODIMENTS

### Embodiment 1

The following description discusses Embodiment 1 in accordance with the present invention, with reference to drawings. For easy explanation, in the following description, (i) a direction in which a data signal line extends is defined as a column direction and (ii) a direction in which a scanning signal line extends is defined as a drawing direction. However, as a matter of course, the scanning signal line can extend in a lateral direction or in a longitudinal direction in a state where a liquid crystal display device (or a display panel and an active matrix substrate used in the liquid crystal display device) of the present invention is used (viewed). Note that one pixel region of the active matrix substrate corresponds to one pixel of the display panel.

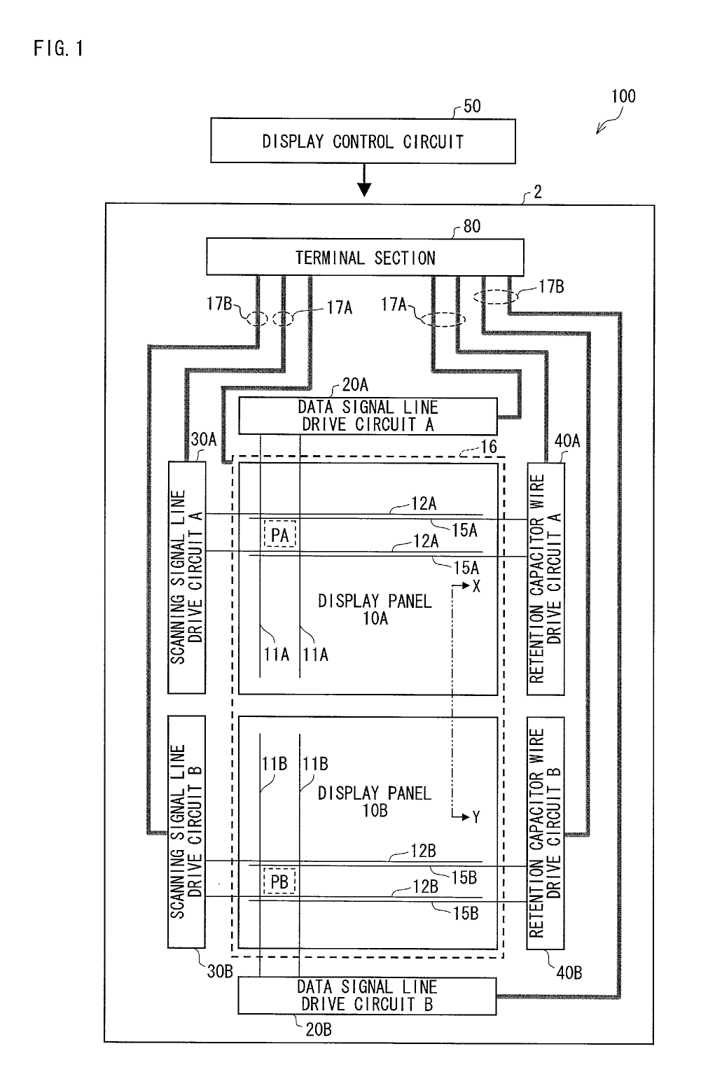

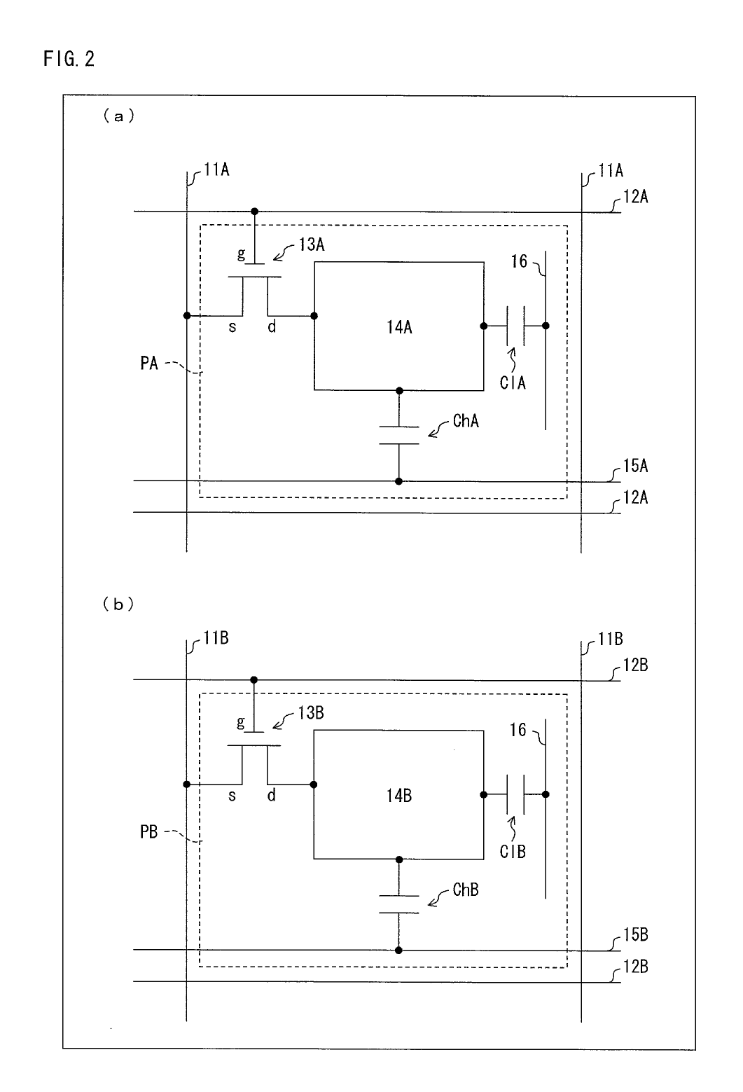

First, the following description discusses, with reference to FIGS. 1 and 2, a configuration of a liquid crystal display device 100 which corresponds to a display device of the present invention. FIG. 1 is a block diagram illustrating an entire configuration of the liquid crystal display device 100. (a) of FIG. 2 is an equivalent circuit diagram illustrating an electric configuration of one pixel of a display panel 10A in the liquid crystal display device 100. (b) of FIG. 2 is an equivalent circuit diagram illustrating an electric configuration of one pixel of a display panel 10B in the liquid crystal display device 100.

The liquid crystal display device 100 includes: the display panels 10A and 10B; data signal line drive circuits 20A and 20B; scanning signal line drive circuits 30A and 30B; retention capacitor wire drive circuits 40A and 40B; and a display control circuit 50.

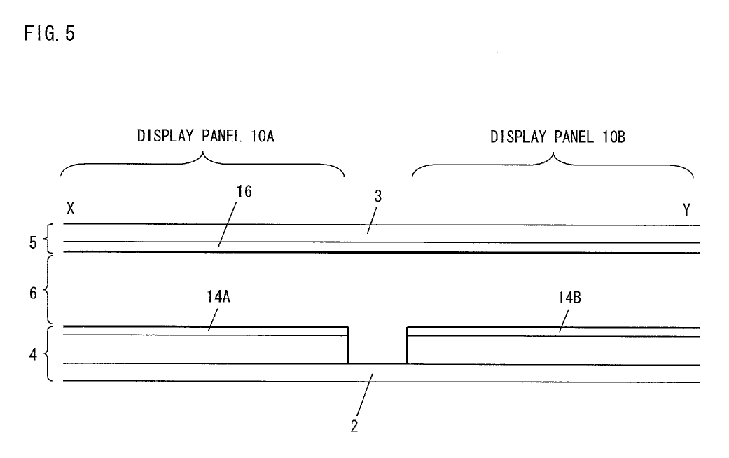

The display panels 10A and 10B are separately provided in respective different regions on a glass substrate 2. The display panel 10A includes data signal lines 11A, scanning signal lines 12A, transistors 13A, pixel electrodes 14A, and retention capacitor wires 15A. Pixels PA are provided so as to correspond to respective intersections of the data signal lines 11A and the scanning signal lines 12A. The display panel 10B includes data signal lines 11B, scanning signal lines 12B, transistors 13B, pixel electrodes 14B, and retention capacitor wires 15B. Pixels PB are provided so as to correspond to respective intersections of the data signal lines 11B and the scanning signal lines 12B. Note that a counter electrode (common electrode) 16 which is common to the display panels 10A and 10B is provided on a counter substrate 3 (see FIG. 5). A constant electric potential (com) is supplied to the counter electrode 16.

In the display panel 10A, (i) the data signal lines 11A are provided, one data signal line 11A per row, so as to be parallel with each other in a column direction (longitudinal direction, top-to-bottom direction of FIGS. 1 and 2), and (ii) the scanning signal lines 12A are provided, one scanning signal line 12A per row, so as to be parallel with each other in a row direction (lateral direction, right and left direction of FIGS. 1 and 2). Further, the retention capacitor wires 15A are provided, one retention capacitor wire 15A per row, so as to be parallel with each other in the column direction. The retention capacitor wires 15A are arranged so that each of the retention capacitor wires 15A is paired with a corresponding one of the scanning signal lines 12A. Transistors 13A are provided so as to correspond to the respective intersections of the data signal line 11A and the scanning signal line 12A. Pixel electrodes 14A are provided so as to correspond to the respective intersections of the data signal line 11A and the scanning signal line 12A. A source electrode s of a transistor 13A is connected with a data signal line 11A. A gate electrode g of a transistor 13A is connected with a scanning signal line 12A. A drain electrode d of a transistor 13A is connected with a pixel electrode 14A. A liquid crystal capacitor ClA is formed between the pixel electrode 14A and the counter electrode 16 via a liquid crystal, and a retention capacitor ChA is formed between the pixel electrode 14A and a retention capacitor wire 15A (see (a) of FIG. 2).

With this configuration, when (i) a gate of the transistor 13A is turned on by means of a gate signal (scanning signal) supplied to the scanning signal line 12A and (ii), accordingly, a source signal (data signal) supplied from the data signal line 11A is written into the pixel electrode 14A, an electric potential is given to the pixel electrode 14A in accordance with the source signal. As a result, a voltage is applied to the liquid crystal interposed between the pixel electrode 14A and the counter electrode 16, in accordance with the source signal. This makes it possible to carry out gradation display in accordance with the source signal.

In the display panel 10B, (i) the data signal lines 11B are provided, one data signal line 11B per row, so as to be parallel with each other in the column direction, and (ii) the scanning signal lines 12B are provided, one scanning signal line 12B per row, so as to be parallel with each other in the row direction. Further, the retention capacitor wires 15B are provided, one retention capacitor wire 15B per row, so as to be parallel with each other in the column direction. The retention capacitor wires 15B are arranged so that each of the retention capacitor wires 15B is paired with a corresponding one of the scanning signal lines 12B. Transistors 13B are provided so as to correspond to the respective intersections of the data signal lines 11B and the scanning signal lines 12B. Pixel electrodes 14B are provided so as to correspond to the respective intersections of the data signal lines 11B and the scanning signal lines 12B. A source electrodes of a transistor 13B is connected with a data signal line 11B. A gate electrode g of a transistor 13B is connected with a scanning signal line 12B. A drain electrode d of a transistor 13B is connected with a pixel electrode 14B. A liquid crystal capacitor ClB is formed between the pixel electrode 14B and the counter electrode 16 via a liquid crystal, and a retention capacitor ChB is formed between the pixel electrode 14B and a retention capacitor wire 15B (see (b) of FIG. 2).

With this configuration, when (i) a gate of the transistor 13B is turned on by means of a gate signal (scanning signal) supplied to the scanning signal line 12B and (ii), accordingly, a source signal (data signal) supplied from the data signal line 11B is written into the pixel electrode 14B, an electric potential is given to the pixel electrode 14B in accordance with the source signal. As a result, a voltage is applied to the liquid crystal interposed between the pixel electrode 14B and the counter electrode 16, in accordance with the source signal. This makes it possible to carry out gradation display in accordance with the source signal.

The display panel 10A having a configuration as described above is driven by the data signal line drive circuit 20A, the scanning signal line drive circuit 30A, and the retention capacitor wire drive circuit 40A. The display panel 10B is driven by the data signal line drive circuit 20B, the scanning signal line drive circuit 30B, and the retention capacitor wire drive circuit 40B. The display control circuit 50 supplies various signals to the data signal line drive circuit 20A and 20B, the scanning signal line drive circuit 30A and 30B, and the retention capacitor wire drive circuit 40A and 40B, which various signals are necessary for driving the display panels 10A and 10B. Note that the display control circuit 50 (i) can be provided in an outside region which is different from regions in which respective drive circuits are provided, or (ii) can be provided on the substrate 2, on which the drive circuits are provided.

In the liquid crystal display device 100, in an active period (valid scanning period) in a vertical scanning period which is periodically repeated, (i) horizontal scanning periods are sequentially allocated to rows and (ii) the rows are sequentially scanned. As such, gate signals, each of which is for turning on a transistor 13A, are supplied from the scanning signal line drive circuit 30A sequentially to the scanning signal lines 12A of the display panel 10A in synchronization with horizontal scanning periods of respective rows. Gate signals, each of which is for turning on a transistor 13B, are supplied from the scanning signal line drive circuit 30B sequentially to the scanning signal lines 12B of the display panel 10B in synchronization with horizontal scanning periods of respective rows.

Further, source signals are supplied from the data signal line drive circuit 20A to the respective data signal lines 11A of the display panel 10A, and source signals are supplied from the data signal line drive circuit 20B to the respective data signal lines 11B of the display panel 10B. The source signals supplied to the data signal lines 11A are signals which are obtained by (i) supplying video signals from an outside of the liquid crystal display 100 to the data signal line drive circuit 20A via the display control circuit 50, (ii) allocating the video signals to respective rows by means of the data signal line drive circuit 20A and (iii) subjecting the video signals to a process such as boosting by means of the data signal line drive circuit 20A. The source signals supplied to the data signal lines 11B are signals which are obtained by (i) supplying video signals from an outside of the liquid crystal display 100 to the data signal line drive circuit 20B via the display control circuit 50, (ii) allocating the video signals to respective rows by means of the data signal line drive circuit 20B and (iii) subjecting the video signals to a process such as boosting by means of the data signal line drive circuit 20B.

Further, a CS signal is supplied from the retention capacitor wire drive circuit 40A to each of the retention capacitor wires 15A of the display panel 10A, and a CS signal is supplied from the retention capacitor wire drive circuit 40B to each of the retention capacitor wires 15B of the display panel 10B. Each of these CS signals is set, for example, to the constant electric potential (com).

The display control circuit 50 controls the data signal line drive circuits 20A and 20B, the scanning signal line drive circuits 30A and 30B, and the retention capacitor wire drive circuits 40A and 40B to output various signals. Note that details of a driving method are described later.

As described above, in the liquid crystal display device 100, the display panels 10A and 10B are provided in the respective different regions on the substrate 2. A drive circuit corresponding to the display panel 10A and a drive circuit corresponding to the display panel 10B are separately provided, and a signal line corresponding to the display panel 10A and a signal line corresponding to the display panel 10B are separately provided. As such, each of the display panels 10A and 10B can be driven independently.

Accordingly, it is possible to apply different driving methods to the respective display panels 10A and 10B.

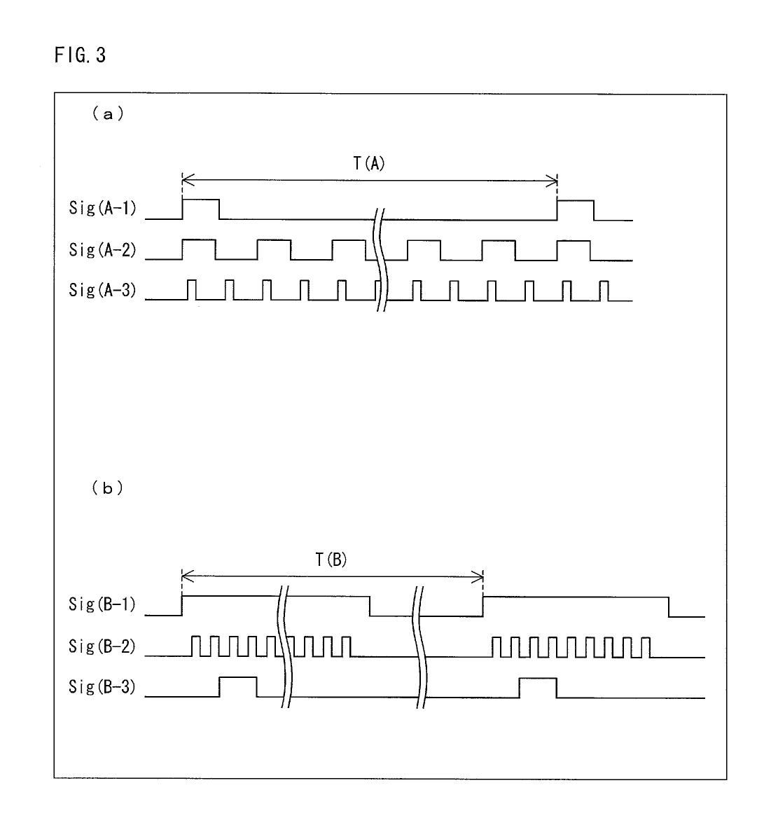

(a) of FIG. 3 is a timing diagram of input signals (Sig (A-1), Sig (A-2), and Sig (A-3)) in the display device 10A. (b) of FIG. 3 is a timing diagram of input signals (Sig (B-1), Sig (B-2), and Sig (B-3)) in the display device 10B. As shown in FIG. 3, a frequency, a cycle (e.g., T (A) and T (B)), and a duty ratio of an input signal can differ between the display panels 10A and 10B.

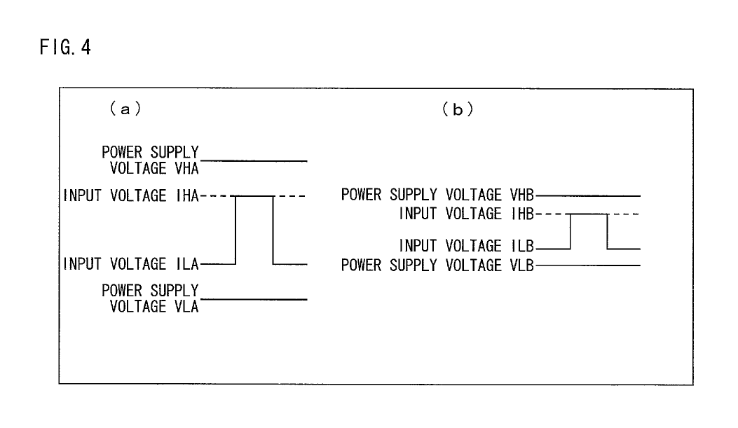

(a) of FIG. 4 is a view showing a range of a power supply voltage supplied to the display panel 10A. (b) of FIG. 4 is a view showing a range of a power supply voltage supplied to the display panel 10B. As shown in FIG. 4, for example, it is possible to (i) a power supply voltage VHA on a high electric potential side of the display panel 10A can be set to a value higher than a power supply voltage VHB on a high electric potential side of the display panel 10B and (ii) a power supply voltage VLA on a low electric potential side of the display panel 10A can be set to a value smaller than a power supply voltage VLB on a low electric potential side of the display panel 10B. This allows a range of an input voltage of the display panel 10A to be wider than a range of an input voltage of the display panel 10B. Specifically, for example, VHA can be set to 10 V, VLA can be set to −5 V, VHB can be set to 5 V, and VLB can be set to 0 V.

As described above, various signals can be set in accordance with each of the display panels 10A and 10B. As such, for example, it is also possible to employ a configuration in which (i) 1-line (1H) inversion driving is carried out in the display panel 10A and (ii) 2-line (2H) inversion driving is carried out in the display panel 10B. In this case, source signals outputted from the data signal line drive circuit 20A are set so that (i) polarities of the source signals are reversed every line and (ii) all pixels in the same row are supplied with source signals having the same polarity. Signals outputted from the data signal line drive circuit 20B are set so that (i) polarities of the source signals are reversed every two lines and (ii) all pixels in the same row are supplied with source signals having the same polarity.

It is also possible to employ a configuration in which the display panels 10A and 10B carry out display with respective different resolutions. For example, it is possible to carry out display at equal magnification in the display panel 10A and carry out display at 2× magnification in the display panel 10B. In this case, in order to carry out display by doubling a resolution of a video signal in the row direction and the column direction, the data signal line drive circuit 20A sets source signals so that (i) a voltage polarity and a gray scale of a source signal supplied to a first row are equal to a voltage polarity and a gray scale of a source signal supplied to a second row and (ii) a voltage polarity and a gray scale of a source signal supplied to a third row are equal to a voltage polarity and a gray scale of a source signal supplied to a fourth row.

The liquid crystal display device 100 is not limited to these driving methods. Various driving methods can be applied to the liquid crystal display device 100.

Further, since each of the display panels 10A and 10B can be independently controlled in the liquid crystal display device 100, it is possible to control driving in accordance with a situation in which the liquid crystal display device 100 is used. For example, it is possible to (1) drive both the display panels 10A and 10B, (2) drive the display panel 10A and stop driving the display panel 10B, (3) stop driving the display panel 10A and drive the display panel 10B, or (4) stop driving the display panels 10A and 10B.

Here, for example, in a configuration of (3) as described above in which driving the display panel 10A is stopped and the display panel 10B is driven, (i) it is possible to cause the data signal line drive circuit 20A and the scanning signal line drive circuit 30A to be stopped by setting a drive signal and a power supply voltage of the display panel 10A to GND, and (ii) it is possible to bring the data signal line drive circuit 20A and the scanning signal line drive circuit 30A into a standby state by setting the drive signal to GND and setting the power supply voltage to a voltage as normally set.

According to the configuration, it is possible to completely stop driving one of the display panels. This allows a reduction in electric power consumption.

Further, in the liquid crystal display device, (i) input signal lines 17A for supplying, to the display panel 10A, a signal supplied from the display control circuit 50 via a terminal section 80 and (ii) input signal lines 17B for supplying, to the display panel 10B, a signal supplied from the display control circuit 50 via the terminal section 80 do not intersect each other. Specifically, in FIG. 1, the input signal lines 17B for supplying, to the display panel 10B, the signal supplied from the display control circuit 50 via the terminal section 80 are provided on an outer side of the input signal lines 17A for providing, to the display panel 10A, the signal supplied from the display control circuit 50 via the terminal section 80. This configuration makes it possible to reduce an influence of cross talk between an input signal line 17A and an input signal line 17B. The configuration is therefore particularly suitable for a case in which the display panels 10A and 10B are driven in respective different manners. Note that each of the input signal lines 17B provided on the outer side is preferably a metal wire made from a material, such as Al, which has a low resistance. This allows a reduction in wire width, so that a width of a frame of each of the display panels can be reduced.

The following description discusses a configuration of a cross section of the liquid crystal display device 100. FIG. 5 is a schematic cross-sectional view taken along arrow X-Y in FIG. 1. Note that signal lines and insulating films have well-known configurations, and are therefore omitted in FIG. 5.

As illustrated in FIG. 5, each of the display panels 10A and 10B is constituted by an active matrix substrate 4, a color filter substrate 5 facing the active matrix substrate 4, and a liquid crystal layer 6 provided between the active matrix substrate 4 and the color filter substrate 5. The active matrix substrate 4 is arranged such that (i) the scanning signal lines 12A and the retention capacitor wires 15A (not shown) are provided on the glass substrate (substrate) 2 in a region corresponding to the display panel 10A, (ii) the scanning signal lines 12B and the retention capacitor wires 15B (not shown) are provided on the glass substrate (substrate) 2 in a region corresponding to the display panel 10B, and (iii) a gate insulating film (not shown) is provided so as to cover the scanning signal lines 12A, the retention capacitor wires 15A, the scanning signal lines 12B, and the retention capacitor wires 15B. In an upper layer of the gate insulating film, (i) the data signal lines 11A (not shown) are provided in the region corresponding to the display panel 10A, and (ii) the data signal lines 11B (not shown) are provided in the region corresponding to the display panel 10B. Note that in the upper layer of the gate insulating film, (i) a semiconductor layer (i layer and n+ layer), the source electrode, and the drain electrode of each of the transistors 13A (not shown) are provided in the region corresponding to the display panel 10A, the source electrode and the drain electrode being in contact with the n+ layer, and (ii) a semiconductor layer (i layer and n+ layer), the source electrode, and the drain electrode of each of the transistors 13B (not shown) are provided in the region corresponding to the display panel 10B, the source electrode and the drain electrode being in contact with the n+ layer. Further, an inorganic interlayer insulating film (not shown) is provided so as to cover a metal layer that includes data signal lines. An organic interlayer insulating film (not shown) having a thickness larger than that of the inorganic interlayer insulating film is provided on the inorganic interlayer insulating film. On the organic interlayer insulating film, (i) the pixel electrodes 14A are provided in the region corresponding to the display panel 10A, and (ii) the pixel electrodes 14B are provided in the region corresponding to the display panel 10B. Further, an alignment film is provided so as to cover the pixel electrodes 14A and the pixel electrodes 14B.

On the other hand, the color filter substrate 5 is arranged such that (i) a black matrix and a colored layer (color filter layer) (not shown) are formed on the glass substrate (counter substrate) 3, (ii) the counter electrode 16 which is common to the regions corresponding to the respective display panels 10A and 10B is formed in an upper layer of the colored layer and the black matrix, and (iii) an alignment film is formed so as to cover the counter electrode 16.

Next, a method for manufacturing the display panels 10A and 10B having the configuration above is described. The method for manufacturing the display panels 10A and 10B includes a step of manufacturing the active matrix substrate 4, a step of manufacturing the color filter substrate 5, and a step of assembling the display panels 10A and 10B by (i) bonding the active matrix substrate 4 and the color filter substrate 5 to each other and (ii) supplying a liquid crystal so as to fill in between the active matrix substrate 4 and the color filter substrate 5.

First, on a substrate (the glass substrate 2 in FIG. 5) made from glass, a plastic, or the like, (i) a metal film of titanium, chrome, aluminum, molybdenum, tantalum, tungsten, copper, or the like, (ii) an alloy film of these metals, or (iii) a laminated film (1000 Å to 3000 Å in thickness) of these films is formed by sputtering. Subsequently, patterning is carried out by Photo Engraving Process (which is hereinafter referred to as “PEP” and includes an etching process) so as to form the scanning signal lines 12A and 12B (the gate electrodes of the transistors 13A and the gate electrodes of the transistors 13B) and the retention capacitor wires 15A and 15B.

Next, an inorganic insulating film (about 3000 Å to 5000 Å in thickness) made from silicon nitride, silicon oxide, or the like is formed by CVD (Chemical Vapor Deposition) over the entire substrate, on which the scanning signal lines 12A and 12B and the retention capacitor wires 15A and 15B have been formed. Then, photoresist is removed so as to form a gate insulating film.

Subsequently, on the gate insulating film (over the entire substrate), an intrinsic amorphous silicon film (1000 Å to 3000 Å in thickness) and an n+ amorphous silicon film (400 Å to 700 Å in thickness) which is doped with phosphorus are sequentially formed by CVD. Then, patterning is carried out by PEP, and photoresist is removed. Thus, a silicon laminate which is constituted by the intrinsic amorphous silicon film and the n+ amorphous silicon film is formed on the gate electrode so as to have an island shape.

Subsequently, over the entire substrate on which the silicon laminate has been formed, (i) a metal film of titanium, chrome, aluminum, molybdenum, tantalum, tungsten, copper, or the like, (ii) an alloy film of these metals, or (iii) a laminated film (1000 Å to 3000 Å in thickness) of these films is formed by spattering. Then, patterning is carried out by PEP, so that the data signal lines 11A and 11B, the source electrode and the drain electrode of each of the transistors 13A and 13B, a drain extraction electrode, a capacitor electrode, and an extension wire are formed (metal layer is formed). Here, resist is removed if necessary.

Further, (i) photoresist at the time of forming metal wires as described above or (ii) the source electrodes and the drain electrodes are used as a mask so as to (a) remove, by etching, the n+ amorphous silicon layer constituting the silicon laminate and (b) remove the photoresist. Thus formed is a channel of each of the transistors. Here, the semiconductor layer can be constituted by an amorphous silicon film as described above, or by a polysilicon film. Further, the amorphous silicon film and the polysilicon film can be subjected to laser annealing so as to have improved properties. This increases a moving speed of an electron in the semiconductor layer, so that properties of the transistors (TFTs) can be improved.

Next, an interlayer insulating film is formed over the entire substrate on which the data signal lines 11A and 11B and the like have been formed. Specifically, by use of mixed gas made up of SiH₄ gas, NH₃ gas, and N₂ gas, an inorganic interlayer insulating film (passivation film) which is made from SiNx and has a thickness of about 3000 Å is formed by CVD so as to cover the entire substrate. Further, an organic interlayer insulating film which is made from a positive photosensitive acrylic resin and has a thickness of about 3 μm is formed by spin coating or die coating.

After this, a contact hole is patterned in the organic interlayer insulating film by PEP, and then the organic interlayer insulating film is burned. Further, (i) the inorganic interlayer insulating film or (ii) the inorganic interlayer insulating film and the gate insulating film are removed by etching by use of a pattern of the organic interlayer insulating film. Thus formed is the contact hole.

Subsequently, a transparent conductive layer (1000 Å to 2000 Å in thickness) made from ITO (Indium Tin Oxide), IZO (Indium Zinc Oxide), zinc oxide, tin oxide, or the like is formed, by spattering, on the interlayer insulating film (over the entire substrate) in which the contact hole has been formed. Then, patterning is carried out by PEP, and resist is removed. Thus formed are the pixel electrodes 14A and 14B.

Lastly, a polyimide resin is printed on the pixel electrodes 14A and 14B (over the entire substrate) so as to have a thickness of 500 Å to 1000 Å. The polyimide resin is then burned and rubbed in one direction by means of a rotating cloth so as to form the alignment film. Thus manufactured is the active matrix substrate 4.

The following description discusses the step of manufacturing the color filter substrate 5.

First, (i) a chromium thin film or (ii) a film of a resin containing a black pigment is formed on a substrate (over the entire counter substrate) made from glass, a plastic, or the like, and then patterning is carried out by PEP so as to form a black matrix. Next, a color filter layer (about 2 μm in thickness) of red, green, and blue is patterned in a gap of the black matrix by a pigment dispersion method or the like.

Subsequently, a transparent conductive layer made from ITO, IZO, zinc oxide, tin oxide, or the like (about 1000 Å in thickness) is formed on the color filter layer (over the entire substrate) so as to form a counter electrode 16 (com).

Lastly, a polyimide resin is printed on the counter electrode 16 (over the entire substrate) so as to have a thickness of 500 Å to 1000 Å, and then burned and rubbed in one direction by use of a rotating cloth so as to form an alignment film. Thus, the color filter substrate can be manufactured.

The following description discusses the step of assembling the display panels 10A and 10B.

First, (i) on one of the active matrix substrate 4 and the color filter substrate 5, a sealing material made from a thermosetting epoxy resin or the like is applied, by screen printing, into a frame pattern having a missing part which serves as a liquid crystal inlet and (ii) on the other of the active matrix substrate 4 and the color filter substrate 5, spherical spacers each of which has a diameter equivalent to a thickness of the liquid crystal layer and is made from a plastic or silica are scattered. Note that, instead of scattering the spacers, it is possible to form the spacers by PEP on the black matrix of the color filter substrate 5 or on the metal wires of the active matrix substrate 4.

Next, the active matrix substrate 4 and the color filter substrate 5 are bonded to each other, and the sealing material is hardened.

Lastly, the liquid crystal layer 6 is formed by (i) injecting a liquid crystal material by an evacuation method into a space surrounded by the active matrix substrate 4, the color filter substrate 5, and the sealing material, (ii) subsequently applying a UV curable resin to the liquid crystal inlet, and (iii) then sealing the liquid crystal material by UV irradiation.

In this manner, the display panels 10A and 10B are manufactured in respective different regions on a single substrate in a single manufacturing process.

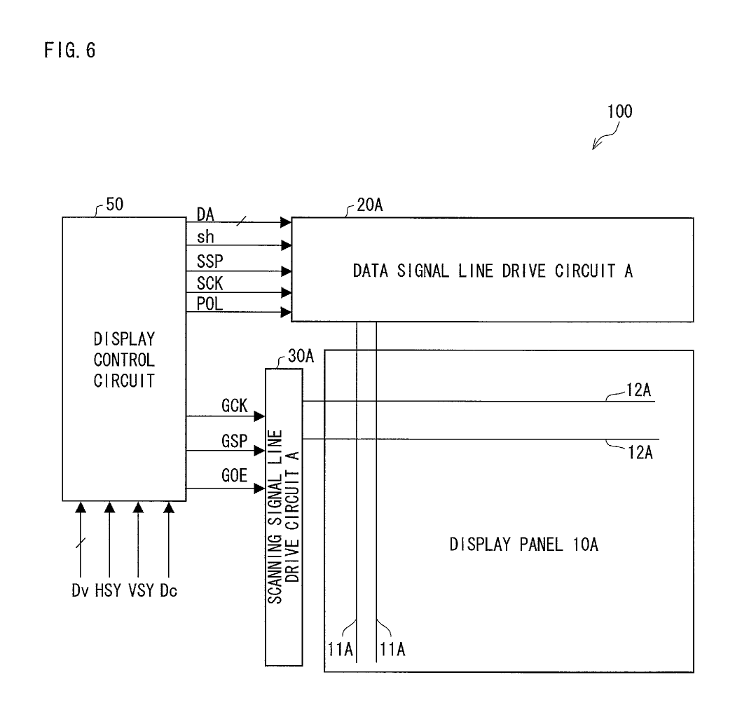

Next, the following description discusses an example of a basic method for driving the liquid crystal display device 100. In the description, the retention capacitor wire drive circuits 15A and 15B are omitted for easy explanation. Note that, since the display panels 10A and 10B can be driven independently, the following description is given on the display panel 10A as an example. FIG. 6 is a block diagram illustrating the method for driving the liquid crystal display device 100.

The display control circuit 50 receives, from an external signal source (e.g., tuner), (i) a digital video signal Dv representing an image to be displayed, (ii) a horizontal sync signal HSY and a vertical sync signal VSY, each of which corresponds to the digital video signal Dv, and (iii) a control signal Dc for controlling display operation. On the basis of the signals Dv, HSY, VSY, and Dc thus received, the display control circuit 50 generates and outputs, as signals for causing the image represented by the digital video signal Dv to be displayed on a display section, (i) a data start pulse signal SSP, (ii) a data clock signal SCK, (iii) a charge share signal sh, (iv) a digital image signal DA representing the image to be displayed (signal corresponding to the video signal Dv), (v) a gate start pulse signal GSP, (vi) a gate clock signal GCK, and (vii) a gate driver output control signal (scanning signal output control signal) GOE.

More specifically, the video signal Dv is subjected to timing adjustment in an internal memory if necessary, and then outputted from the display control circuit 50 as the digital image signal DA. The data clock signal SCK is generated as a signal constituted by pulses which correspond to respective pixels of the image represented by the digital image signal DA. On the basis of the horizontal sync signal HSY, the data start pulse signal SSP is generated as a signal which is at a high level (H level) only for a predetermined period in each horizontal scanning period. On the basis of the vertical sync signal VSY, the gate start pulse signal GSP is generated as a signal which is at a H level only for a predetermined period in each frame period (vertical scanning period). The gate clock signal GCK is generated on the basis of the horizontal sync signal HSY. The charge share signal sh and the gate driver output control signal GOE are generated on the basis of the horizontal sync signal HSY and the control signal Dc.

Among the signals thus generated in the display control circuit 50, (i) the digital image signal DA, the charge share signal sh, a signal POL for controlling a polarity of a signal potential (data signal potential), the data start pulse signal SSP, and the data clock signal SCK are supplied to the data signal line drive circuit 20A, and (ii) the gate start pulse signal GSP, the gate clock signal GCK, and the gate driver output control signal GOE are supplied to the scanning signal line drive circuit 30A.

On the basis of the digital image signal DA, the data clock signal SCK, the charge share signal sh, the data start pulse signal SSP, and the polarity inversion signal POL, the data signal line drive circuit 20A sequentially generates analog electric potentials (signal potentials) every horizontal scanning period, which analog electric potentials are equivalent to pixel values, on each of the scanning signal lines 12A, of the image represented by the digital image signal DA. The data signal line drive circuit 20A then supplies these data signals to the data signal line 11A.

On the basis of the gate start pulse signal GSP, the gate clock signal GCK, and the gate driver output control signal GOE, the scanning signal line drive circuit 30A generates and supplies gate on-pulse signals to the scanning signal lines 12A, so that the scanning signal lines 12A are selectively driven.

When a data signal line 11A and a scanning signal line 12A of the display panel 10A are driven by the data signal line drive circuit 20A and the scanning signal line drive circuit 30A as described above, a signal potential is written from the data signal line 11A into a pixel electrode 14A via a transistor 13A that is connected to the scanning signal line 12A thus selected. This causes a voltage to be applied to the liquid crystal layer 6 of each pixel PA, so that an amount of transmitted light out of light supplied from the backlight is controlled. In this manner, the image represented by the digital video signal Dv is displayed on the pixels PA.

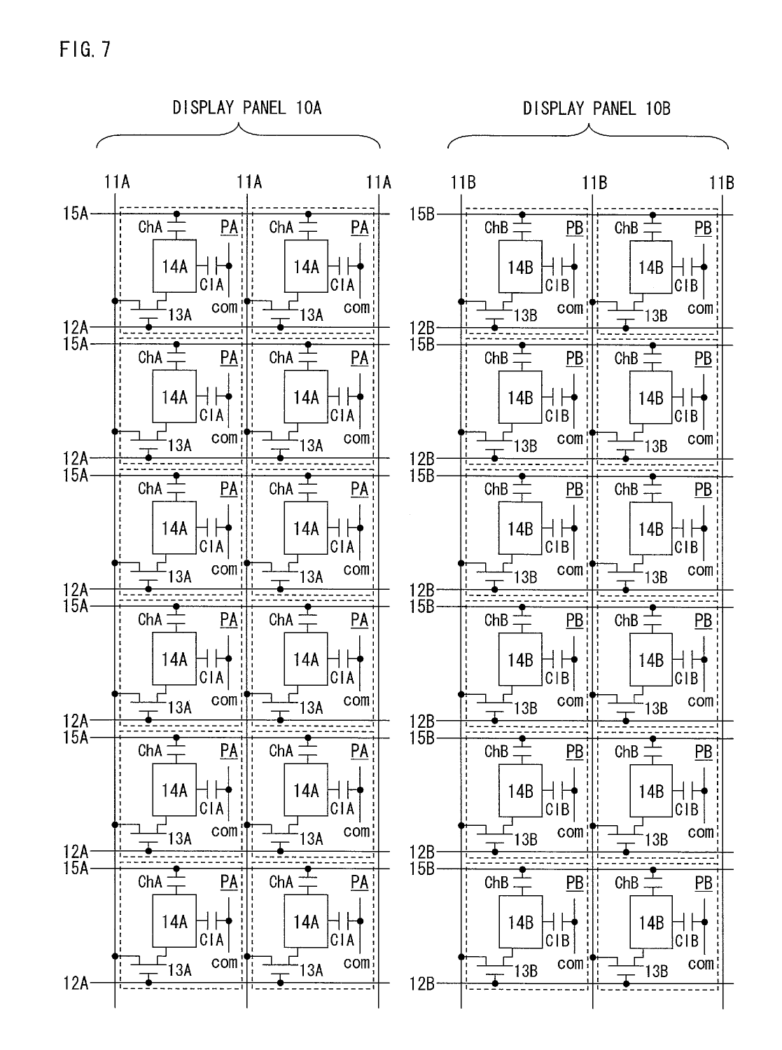

Next, the following description discusses an example of a configuration of the liquid crystal display device 100 of Embodiment 1. FIG. 7 is an equivalent circuit diagram partially illustrating each of the display panels 10A and 10B of a liquid crystal display panel 100 in accordance with Configuration Example 1. As illustrated in FIG. 7, in the liquid crystal display device 100 of Configuration Example 1, the display panels 10A and 10B have identical configurations. For convenience, the display panels 10A and 10B are arranged side by side in a lateral direction on the sheet of FIG. 7. Note, however, that a direction in which the display panels 10A and 10B are arranged side by side is not limited to a specific one.

In the display panel 10A, (i) the data signal lines 11A extending in the column direction are arranged in order, (ii) the scanning signal lines 12A extending in the row direction are arranged in order, and (iii) the retention capacitor wires 15A extending in the row direction are arranged in order so that each of the retention capacitor wires 15A is paired with a corresponding one of the scanning signal lines 12A. Pixels PA are provided so as to correspond to respective intersections of the data signal lines 11A and the scanning signal lines 12A. A pixel electrode 14A is provided in each of the pixels PA and is connected with a data signal line 11A via a transistor 13A connected with a scanning signal line 12A. In this configuration, (i) the retention capacitor ChA is formed between the pixel electrode 14A and the retention capacitor wire 15A and (ii) the liquid crystal capacitor ClA is formed between the pixel electrode 14A and the counter electrode (com).

Similarly, in the display panel 10B, (i) the data signal lines 11B extending in the column direction are arranged in order, (ii) the scanning signal lines 12B extending in the row direction are arranged in order, and (iii) the retention capacitor wires 15B extending in the row direction are arranged in order so that each of the retention capacitor wires 15B is paired with a corresponding one of the scanning signal lines 12B. Pixels PB are provided so as to correspond to respective intersections of the data signal lines 11B and the scanning signal lines 12B. A pixel electrode 14B is provided in each of the pixels PB and is connected with a data signal line 11B via a transistor 13B that is connected with a scanning signal line 12B. In this configuration, (i) the retention capacitor ChB is formed between the pixel electrode 14B and the retention capacitor wire 15B and (ii) the liquid crystal capacitor ClB is formed between the pixel electrode 14B and the counter electrode (com).

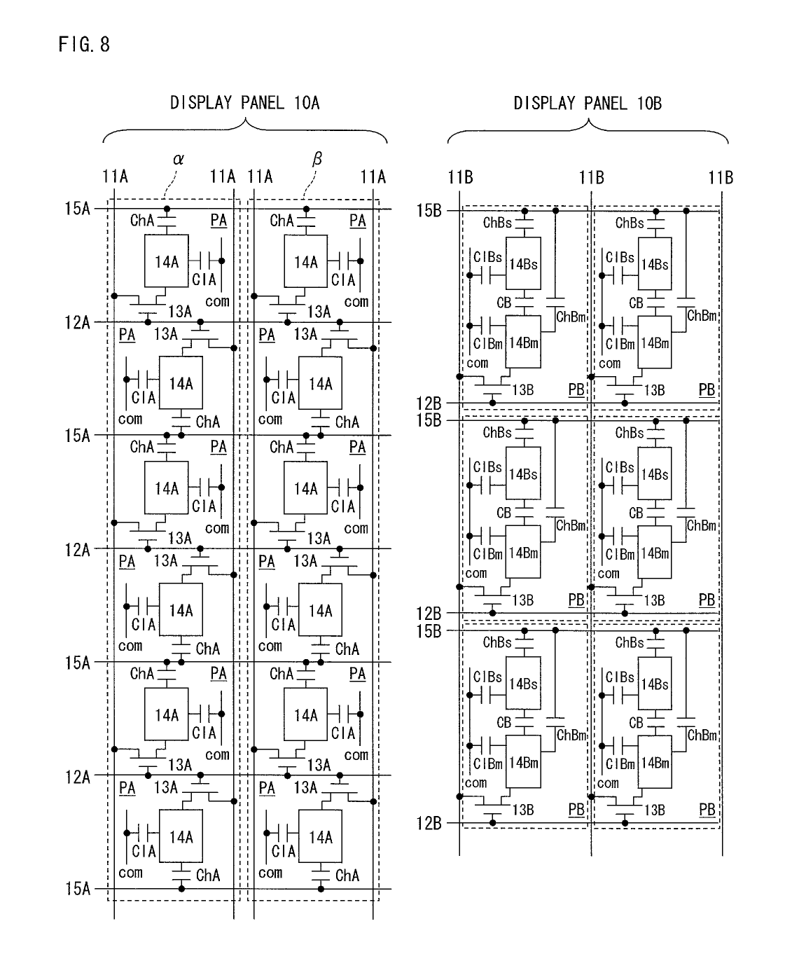

FIG. 8 is an equivalent circuit diagram partially illustrating each of the display panels 10A and 10B of a liquid crystal display panel 100 in accordance with Configuration Example 2. As illustrated in FIG. 8, in the liquid crystal display panel 100 in accordance with Configuration Example 2, an arrangement of the data signal lines 11A, the scanning signal lines 12A, the transistors 13A, the pixel electrodes 14A, and the retention capacitor wires 15A in the display panel 10A is different from an arrangement of the data signal lines 11B, the scanning signal lines 12B, the transistors 13B, the pixel electrodes 14B, and the retention capacitor wires 15B in the display panel 10B.

In the display panel 10A, (i) two data signal lines 11A are provided so as to correspond to each pixel line and (ii) one scanning signal line 12A and one retention capacitor wire 15A are provided so as to each correspond to two pixels that are adjacent to each other in the column direction. Further, in each of pixel lines α and β, a pixel electrode 14A included in one of two pixels PA adjacent to each other in the column direction is connected with a data signal line 11A via a transistor 13A, which data signal line 11A is different from a data signal line 11A with which a pixel electrode 14A included in the other of the two pixels PA is connected via a transistor 13A. The retention capacitor ChA is formed between the pixel electrode 14A and the retention capacitor wire 15A. The liquid crystal capacitor ClA is formed between the pixel electrode 14A and the counter electrode (com).

This configuration allows a data signal potential to be simultaneously written into two adjacent pixels. This makes it possible to (i) increase a speed of rewriting a screen and (ii) increase time for charging the pixels.

By contrast, in the display panel 10B, two pixel electrodes (main pixel electrode 14Bm, sub-pixel electrode 14Bs) are provided in each pixel PB. The main pixel electrode 14Bm is connected with a data signal line 11B via a transistor 13B connected with a scanning signal line 12B, and the sub-pixel electrode 14Bs is connected (capacity coupled) with the main pixel electrode 14Bm via a capacitor CB. A retention capacitor ChBm is formed between the main pixel electrode 14Bm and the retention capacitor wire 15B, and a retention capacitor ChBs is formed between the sub-pixel electrode 14Bs and the retention capacitor wire 15B. A liquid crystal capacitor ClBm is formed between the main pixel electrode 14Bm and the counter electrode (com), and a liquid crystal capacitor ClBs is formed between the sub-pixel electrode 14Bs and the counter electrode (com). A coupling capacitor CB is formed between the main pixel electrode 14Bm and the sub-pixel electrode 14Bs.

This configuration allows a subpixel including the main pixel electrode 14Bm to serve as a bright subpixel and a subpixel including the sub-pixel electrode 14Bs to serve as a dark subpixel. This makes it possible to carry out halftone display by means of the bright subpixel and the dark subpixel, so that a viewing angle characteristic can be improved. Note that three or more pixel electrodes can be provided in each pixel PB.

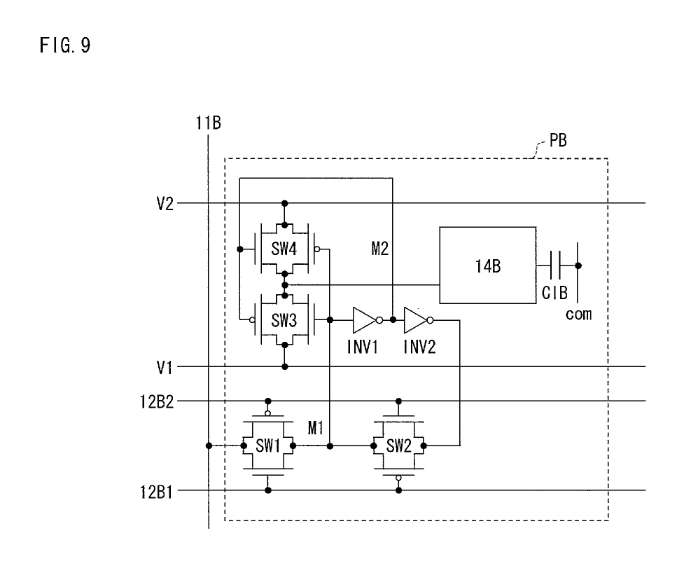

Examples of a configuration in which the display panel 10A and the display panel 10B have respective different pixel arrangements encompass a configuration (Configuration Example 3) in which a DRAM and a SRAM are used together. In a liquid crystal display device 100 of Configuration Example 3, for example, a DRAM-type pixel configuration as illustrated in FIG. 7 can be employed in the display panel 10A, and an SRAM-type pixel configuration as illustrated in FIG. 9 can be employed in the display panel 10B. The following description discusses the SRAM-type pixel configuration applied to the display panel 10B. FIG. 9 schematically illustrates an electric configuration of one pixel PB. In FIG. 9, reference signs 12B1 and 12B2 each indicate a scanning signal line. An inversion signal of data inputted to the scanning signal line 12B1 is inputted to the scanning signal line 12B2. Reference signs SW1 through SW4 each indicate a switching circuit. Reference signs INV1 and INV2 each indicate an inverter. Reference signs M1 and M2 each indicate a memory signal. Reference signs V1 and V2 each indicate a signal for a pixel electrode.

The switching circuits SW1 and SW2 operate in an opposite manner. For example, the switching circuit SW2 is OFF (closed) when the switching circuit SW1 is ON (opened), and the switching circuit SW2 is ON (opened) when the switching circuit SW1 is OFF (closed).

Since an inversion signal of the data inputted to the scanning line signal line 12B1 is inputted to the scanning signal line 12B2, (i) the scanning signal line 12B2 is at a low level when, for example, the scanning signal line 12B1 is at a high level and (ii) the scanning signal line 12B2 is at a high level when the scanning signal line 12B1 is at a low level.

Here, when the scanning signal line 12B1 reaches a high level (the scanning signal line 12B2 is at a low level), the switching circuit SW1 is turned on (opened), so that data on the data signal line 11B is passed through the switching circuit SW1 and written into the memory signal M1.

Next, when the scanning signal line 12B1 reaches a low level (the scanning signal line 12B2 is at a high level), the switching circuit SW2 is turned on (opened), so that the data having been written into the memory signal M1 is held (stored) in a route of the inverter INVI, the memory signal M2, the inverter INV2, the switching circuit SW2, and the memory signal M1.

Note that the switching circuit SW1 is OFF (closed) at this time. As such, even if data (level) on the scanning signal line 11B changes, an electric potential of the data in the memory signal M1 is held (stored) without being affected by the change.

Here, a level of the memory signal M2 is reverse to a level of the memory signal line M1. The switching circuit SW3 and the switching circuit SW4 operate in an opposite manner. For example, the switching circuit SW4 is OFF (closed) when the switching circuit SW3 is ON (closed), and the switching circuit SW4 is ON (opened) when the switching circuit SW3 is OFF (closed).

As such, when the memory signal M1 is at a high level (the memory signal M2 is at a low level), the switching circuit SW3 is ON (opened), so that the signal V1 for a pixel electrode is written into the pixel electrode 14B.

On the other hand, when the memory signal M1 is at a low level (the memory signal M2 is at a high level), the switching circuit SW4 is ON (opened), so that the signal V2 for a pixel electrode is written into the pixel electrode 14B.

Note that each of the signal V1 for a pixel electrode and the signal V2 for a pixel electrode sets an electric potential (level) of a pixel electrode. For example, the signal V1 for a pixel electrode sets a level corresponding to black, and the signal V2 for a pixel electrode sets a level corresponding to white.

Accordingly, the signal V1 for a pixel electrode or the signal V2 for a pixel electrode is written into the pixel electrode 14B in accordance with a level of the data stored in the memory signal M1.

Note that the display panels 10A and 10B are not limited to the configuration examples as described above. The display panels 10A and 10B can have a configuration which is obtained by combining various configurations.

### Embodiment 2

The following description discusses a liquid crystal display device 200 in accordance with Embodiment 2 of the present invention. For easy explanation, the same reference signs will be given to members each having the same function as a member described in Embodiment 1, and descriptions on such a member will be omitted. Further, the terms each defined in Embodiment 1 will be used according to the definition also in Embodiment 2, unless otherwise specified.

In the liquid crystal display device 100 in accordance with Embodiment 1, the counter electrode 16 is shared by the display panels 10A and 10B. In the liquid crystal display device 200, counter electrodes are separately provided for the respective display panels 10A and 10B.

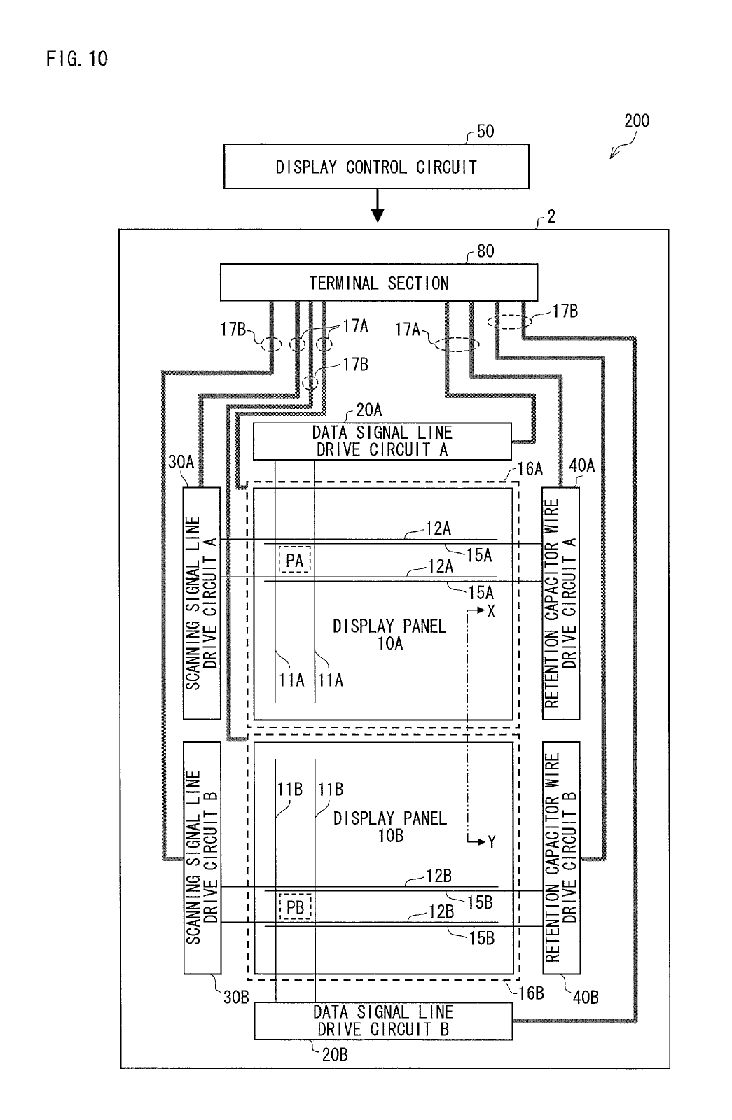

FIG. 10 is a block diagram illustrating an entire configuration of the liquid crystal display device 200. As illustrated in FIG. 10, a counter electrode 16A is provided in the display panel 10A, and a counter electrode 16B is provided in the display panel 10B. Counter electrode potentials COM_A and COM_B are supplied from the display control circuit 50 to the counter electrodes 16A and 16B, respectively.

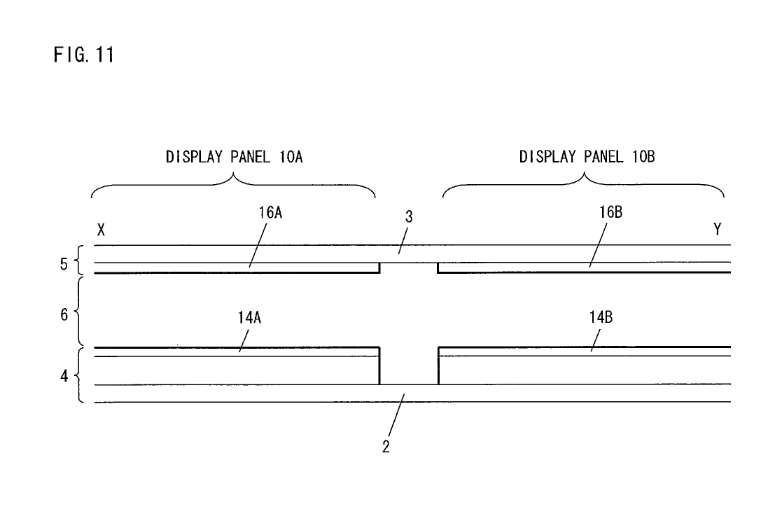

FIG. 11 is a schematic cross sectional view taken along arrow X-Y in FIG. 10. The active matrix substrate 4 has the same configuration as that in the liquid crystal display device 100 in accordance with Embodiment 1 as illustrated in FIG. 5. However, the color filter substrate 5 has the following configuration. The black matrix and the colored layer (color filter) (not shown) are provided on the glass substrate (counter substrate) 3 and, in an upper layer of the black matrix and the colored layer, (i) the counter electrode 16A is provided in a region corresponding to the display panel 10A and (ii) the counter electrode 16B is provided in a region corresponding to the display panel 10B. An alignment film is provided so as to cover the counter electrode 16A and the counter electrode 16B.

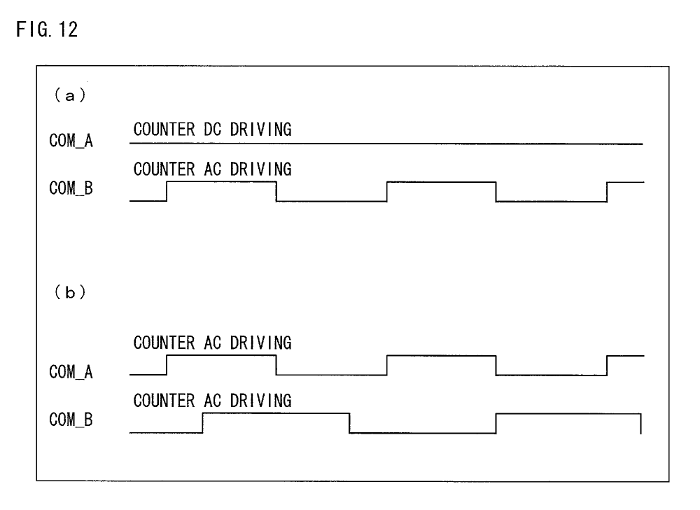

As described above, in the liquid crystal display device 200, (i) the display panels 10A and 10B are provided in respective different regions on the substrate 1 and (ii) a drive circuit, a signal line, and a counter electrode are provided for each of the display panels 10A and 10B. This makes it possible to further improve flexibility in design of a method for driving a liquid crystal display device. For example, as shown in (a) of FIG. 12, by setting (i) a voltage applied to the counter electrode 16A to be a DC voltage and (ii) a voltage applied to the counter electrode 16B to be an AC voltage, it is possible to cause the display panel 10A to be DC driven and the display panel 10B to be AC driven. Further, as shown in (b) of FIG. 12, it is possible to set voltages supplied to the respective counter electrodes 16A and 16B to (i) be AC voltages and (ii) have respective different cycles (frequencies) so that the display panels 10A and 10B can be driven at respective different timings.

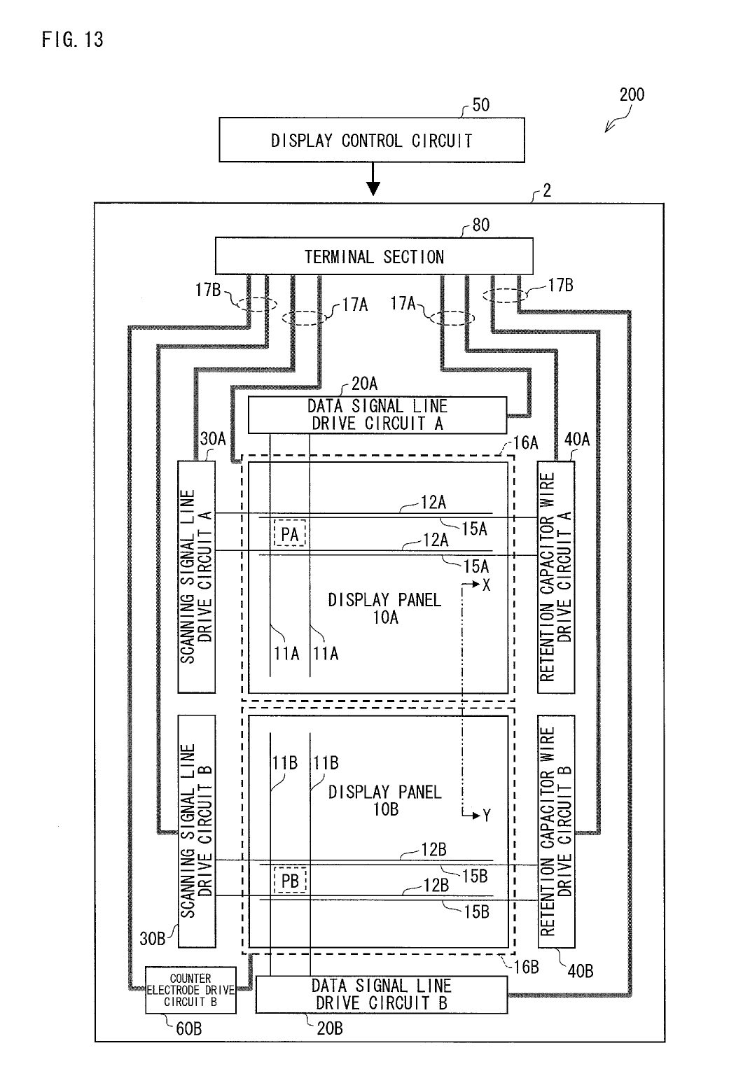

Note that the liquid crystal display device 200 in accordance with Embodiment 2 can have the following configuration. FIG. 13 is a block diagram illustrating an entire configuration of a liquid crystal display device 200 in accordance with Configuration Example 4. As illustrated in FIG. 13, a counter electrode drive circuit 60B which corresponds to the display panel 10B is provided in the liquid crystal display device 200 in accordance with Configuration Example 4. The counter electrode drive circuit 60B (i) generates a counter electrode potential COM_B on the basis of a signal which has been externally supplied and (ii) supplies the counter electrode potential COM_B to the counter electrode 16B.

Although Configuration Example 4 employs a configuration in which a counter electrode potential COM_A to be applied to the counter electrode 16A is supplied from the display control circuit 50, Configuration Example 4 is not limited to this. It is possible to employ a configuration in which, like the display panel 10B, (i) a counter electrode drive circuit 60A (not shown) is provided and (ii) the counter electrode drive circuit 60A generates and supplies the counter electrode potential COM_A to the counter electrode 16A.

Note that the driving methods and the manufacturing method as described in Embodiment 1 can be applied to the liquid crystal display device 200 in accordance with Embodiment 2. As a matter of course, the configurations of the display panels 10A and 10B of the Configuration Example 1 through 3 in Embodiment 1 can be applied to the display panels 10A and 10B in the liquid crystal display device 200.

### Embodiment 3

The following description discusses a liquid crystal display device 300 in accordance with Embodiment 3 of the present invention. For easy explanation, the same reference signs will be given to members each having the same function as a member described in Embodiments 1 and/or 2, and descriptions on such a member will be omitted. Further, the terms each defined in Embodiments 1 and/or 2 will be used according to the definition also in Embodiment 3, unless otherwise specified.

In the liquid crystal display device 300 in accordance with Embodiment 3, (i) the input signal lines 17A for supplying, to the display panel 10A, a signal supplied from the display control circuit 50 via the terminal section 80 and (ii) the input signal lines 17B for supplying, to the display panel 10B, a signal supplied from the display control circuit 50 via the terminal section 80 do not intersect each other. Further, a power line 18A corresponding to the display panel 10A and a power line corresponding to the display panel 10B are provided between (i) the input signal lines 17A and (ii) the input signal lines 17B. Note that a single power line can serve as the power line 18A and the power line 18B.

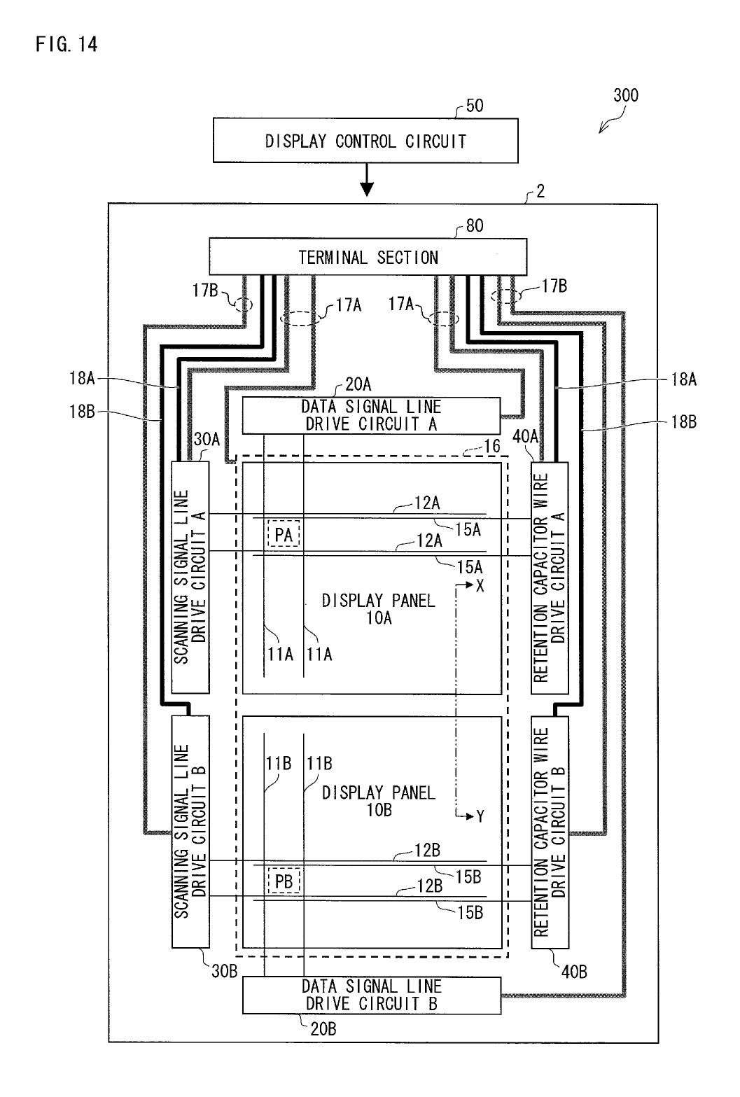

FIG. 14 is a block diagram illustrating an entire configuration of a liquid crystal display device 300 in accordance with Configuration Example 5. In the liquid crystal display device 300 illustrated in FIG. 14, the input signal lines 17B for supplying, to the display panel 10B, a signal supplied from the display control circuit 50 via the terminal section 80 is provided on an outer side of the input signal lines 17A for supplying, to the display panel 10A, a signal supplied from the display control circuit 50 via the terminal section 80. The power line 18A and the power line 18B are provided between (i) the input signal lines 17A and (ii) the input signal lines 17B. By interposing the power line 18A and the power line 18B between (i) the input signal lines 17A and (ii) the input signal lines 17B in this manner, it is possible to further reduce the influence of cross talk as compared with the liquid crystal display device 100 illustrated in FIG. 1.

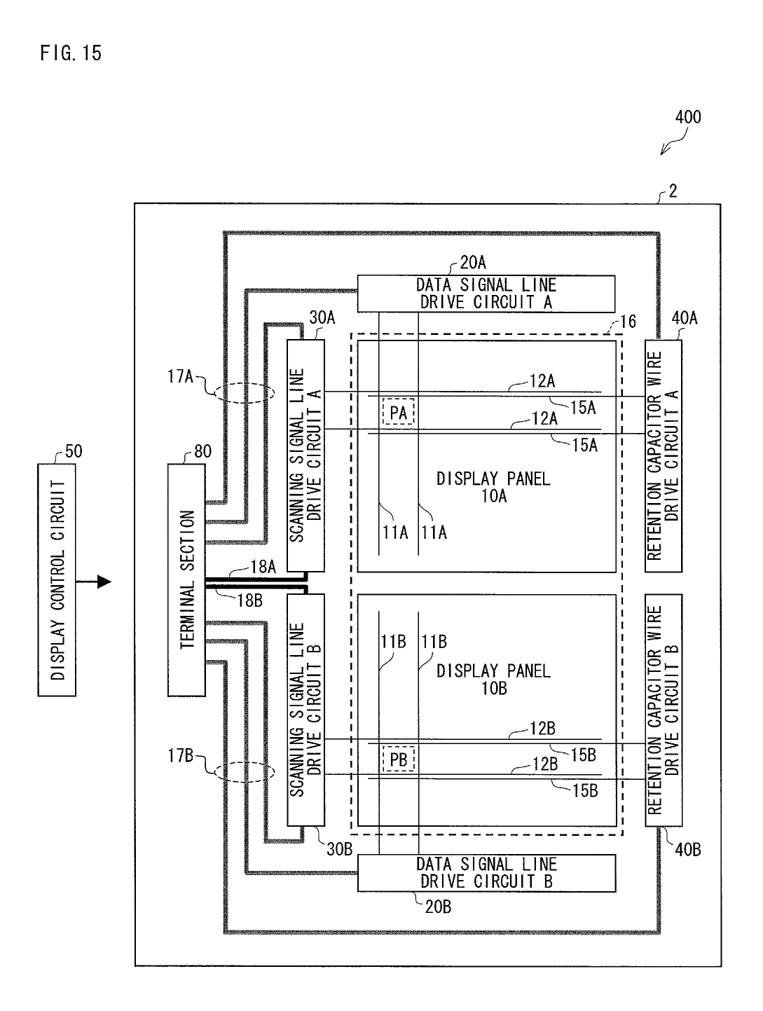

Note that the liquid crystal display device of the present embodiment can have a configuration in which a direction in which the display panels 10A and 10B are arranged side by side is different from a direction in which a signal is supplied from the display control circuit 50 via the terminal section 80, as illustrated in FIG. 15. In a liquid crystal display device 400 in accordance with the configuration (Configuration Example 6), it is possible to obtain the same effect as described above by providing the power lines 18A and 18B in a center part. Note that the configuration, illustrated in FIG. 15, in which the direction in which the display panels 10A and 10B are arranged side by side is different from the direction in which a signal is supplied from the display control circuit 50 via the terminal section 80 can be applied to each of the liquid crystal display devices described in Embodiments 1 and 2.

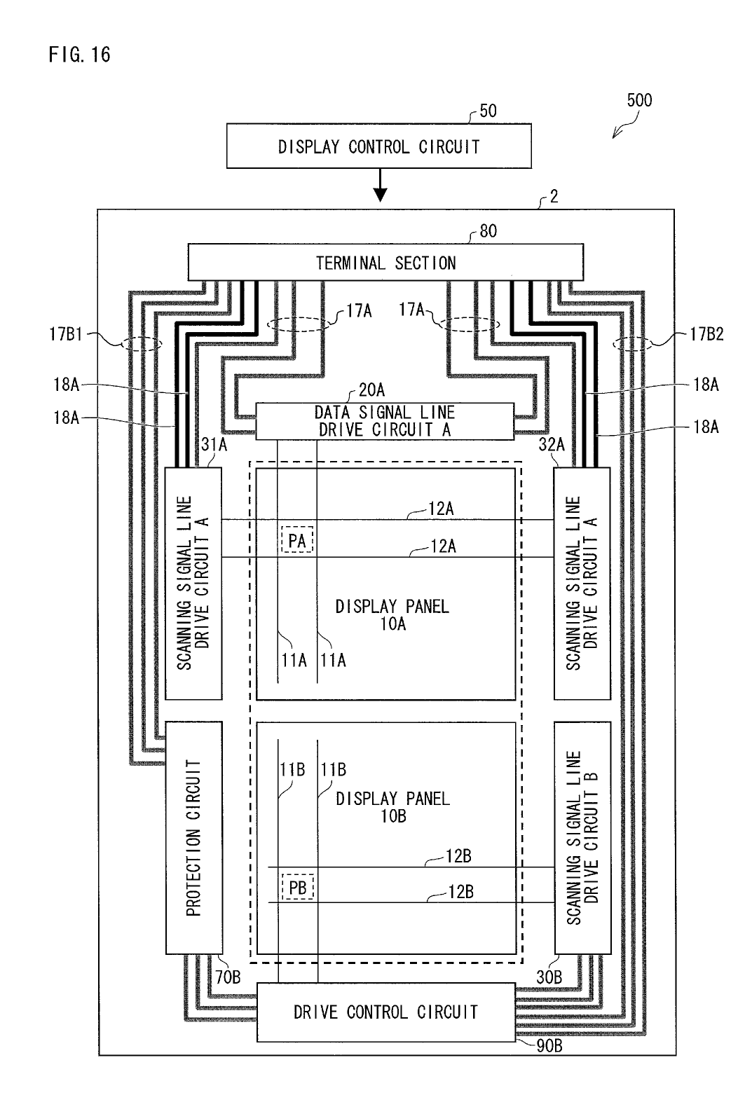

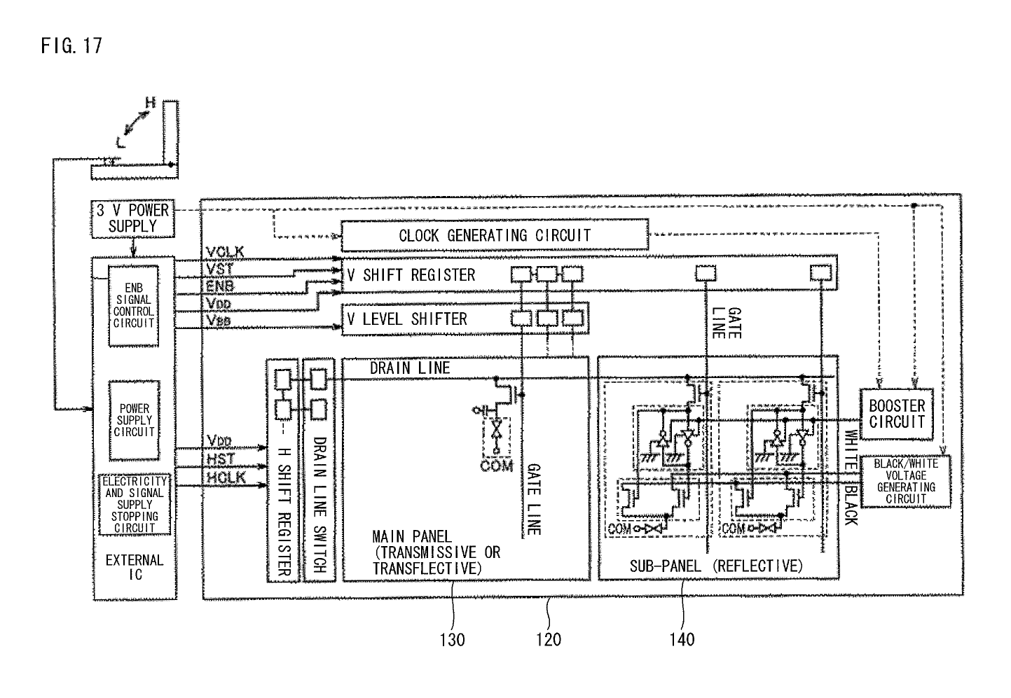

FIG. 16 is a block diagram illustrating an entire configuration of a liquid crystal display device 500 in accordance with Configuration Example 7. As illustrated in FIG. 16, in the liquid crystal display device 500 in accordance with Configuration Example 7, (i) scanning signal line drive circuits 31A and 32A are provided on both sides of the display panel 10A, (ii) a scanning signal line drive circuit 30B is provided on one side of the display panel 10B, (iii) a protection circuit 70B is provided on the other side of the display panel 10B, and (iii) a drive control circuit 90B (data signal line drive circuit, timing generator, common electrode drive circuit, and the like.) is provided at a lower position with respect to the display panel 10B. A signal line which (i) may cause ESD damage due to having a relatively small internal load capacity near a terminal and (ii) therefore requires the protection circuit 70B is allocated to each of the input signal lines 17B1. Signal lines each of which has a large internal load capacity and therefore does not require the protection circuit 70B are allocated to the input signal lines 17B2. A signal supplied to the input signal lines 17B1 is passed through the protection circuit 70B and then supplied to the timing generator. A timing signal generated in the timing generator is supplied to the scanning signal line drive circuit 30B or the data signal line drive circuit. Note that the protection circuit 70B can be provided inside the scanning signal line drive circuit 30B and the data signal line drive circuit.

To the scanning signal line drive circuits 31A and 32A and the data signal line drive circuit 20A of the display panel 10A, respective control signals are supplied via the input signal lines 17A.

Note that the scanning signal line drive circuit 30B of the display panel 10B can be provided on one side of the display panel 10B in the column direction. The data signal line drive circuit, the timing generator, and the common electrode drive circuit, and the like can be provided in a row direction of the display panel 10B.

According to the configuration, it is possible to reduce a width of a frame of each of the display panels 10A and 10B. Further, since the configuration enables an operation equivalent to a case in which each of the display panels 10A and 10B is caused to operate alone, efficient arrangement becomes possible. Furthermore, since all circuits can be arranged on three sides of the display panel 10B, an entire panel can be constituted without arranging a circuit between the display panel 10A and the display panel 10B.

Note that the driving methods and the manufacturing method as described in Embodiment 1 can be applied to the liquid crystal display device 500 in accordance with Embodiment 3. As a matter of course, the configurations of the display panels 10A and 10B of the configurations as described above can be applied to the display panels 10A and 10B in the liquid crystal display device 500.

Further, although each of the liquid crystal display devices 100, 200, 300, 400, and 500 described above has a configuration in which two display panels 10A and 10B are provided on one substrate, the liquid crystal display device of the present invention is not limited to this. It is possible to employ a configuration in which (i) three or more display panels are formed on one substrate and (ii) drive circuits (data signal line drive circuits, scanning signal line drive circuits, and the like) corresponding to the respective display panels are provided separately.

As described above, a display device in accordance with the present invention is a display device including: a substrate; a plurality of display panels provided on the substrate; a plurality of input signal lines for supplying, to the plurality of display panels, an input signal which has been externally supplied, the plurality of input signal lines being provided on the substrate; a plurality of data signal lines provided for each of the plurality of display panels; a plurality of scanning signal lines provided for each of the plurality of display panels; a data signal line drive circuit for driving the plurality of data signal lines, the data signal line drive circuit being provided for each of the plurality of display panels; and a scanning signal line drive circuit for driving the plurality of scanning signal lines, the scanning signal line drive circuit being provided for each of the plurality of display panels, the plurality of input signal lines being arranged so as not to intersect each other in a plan view.

According to the configuration, display panels are provided in respective different regions on a single substrate, and drive circuits and signal lines are provided for each of the display panels. This allows each of the display panels to be driven independently. For example, in a case where two display panels A and B are provided, it is possible to control driving in accordance with a situation in which the display device is used. For example, it is possible to (1) drive both the display panels A and B, (2) drive the display panel A and stop driving the display panel B, (3) stop driving the display panel A and drive the display panel B, or (4) stop driving the display panels A and B. This makes it possible to reduce electric power consumption and increase flexibility in design.

Further, according to the configuration, it is possible to reduce an influence of cross talk between an input signal line corresponding to the display panel A and an input signal line corresponding to the display panel B. The configuration is therefore particularly suitable for a case in which the display panels A and B are driven in respective different manners.

The display device can have a configuration in which the plurality of display panels include a first display panel and a second display panel, the first display panel being provided closer to an input side, to which the input signal is supplied, than the second display panel is; and in a plan view, an input signal line corresponding to the second display panel is provided on an outer side of an input signal line corresponding to the first display panel.

The display device can have a configuration in which power lines corresponding to respective two adjacent display panels among the plurality of display panels are provided between (i) a plurality of input signal lines corresponding to one of the two adjacent display panels and (ii) a plurality of input signal lines corresponding to the other of the two adjacent display panels.

This makes it possible to further reduce an influence of cross talk between an input signal line corresponding to the display panel A and an input signal line corresponding to the display panel B

The display device can further include counter electrodes which are separately provided for the respective plurality of display panels.

The display device can have a configuration in which different electric potentials are supplied to the respective counter electrodes.

In the display device, the plurality of display panels can be constituted by (i) a display panel having a counter electrode to which a DC voltage is supplied and (ii) a display panel having a counter electrode to which an AC voltage is supplied.

According to this configuration, since the counter electrodes are separately provided for the respective display panels, it is possible to further improve flexibility in design of a method for driving a liquid crystal display device. For example, (i) setting a voltage supplied to a counter electrode to be a DC voltage allows a display panel corresponding to the counter electrode to be DC driven, and (ii) setting a voltage supplied to another counter electrode to be an AC voltage allows a display panel corresponding to the another counter electrode to be AC driven.

The display device can further include a counter electrode which is shared by the plurality of display panels and to which a constant electric potential is supplied.

This makes it possible to simplify a configuration of the display device and reduce electric power consumption.

The display device can have a configuration in which the number of the plurality of data signal lines varies among the plurality of display panels; and the number of the plurality of scanning signal lines varies among the plurality of display panels.

The present invention is not limited to the description of the embodiments above, but may be altered by within the technical matters of common knowledge. An embodiment on the basis of a proper combination of the altered embodiments is encompassed in the technical scope of the present invention.

### INDUSTRIAL APPLICABILITY

The display device of the present invention is suitably applied to an electronics device in which a plurality of display sections are provided.

### REFERENCE SIGNS LIST

2, 3 Glass substrate (Substrate)
10A, 10B Display panel
20A, 20B Data signal line drive circuit
30A, 30B Scanning signal line drive circuit
40A, 40B Retention capacitor wire drive circuit
50 Display control circuit
60A, 60B Counter electrode drive circuit
70B Protection circuit
80 Terminal section
90B Drive control circuit
11A, 11B Data signal line
12A, 12B Scanning signal line
13A, 13B Transistor
14A, 14B Pixel electrode
15A, 15B Counter electrode
16A, 16B Retention capacitor wire
17A, 17B Input signal lines
100, 200, 300, 400, 500 Liquid crystal display device (Display device)
PA, PB Pixel

1. A display device comprising:
a substrate;
a plurality of display panels provided on the substrate;
a plurality of input signal lines for supplying, to the plurality of display panels, an input signal which has been externally supplied, the plurality of input signal lines being provided on the substrate;
a plurality of data signal lines provided for each of the plurality of display panels;
a plurality of scanning signal lines provided for each of the plurality of display panels;
a data signal line drive circuit for driving the plurality of data signal lines, the data signal line drive circuit being provided for each of the plurality of display panels; and
a scanning signal line drive circuit for driving the plurality of scanning signal lines, the scanning signal line drive circuit being provided for each of the plurality of display panels,
the plurality of input signal lines being arranged so as not to intersect each other in a plan view.

2. The display device as set forth in claim 1, wherein:
the plurality of display panels include a first display panel and a second display panel, the first display panel being provided closer to an input side, to which the input signal is supplied, than the second display panel is; and
in a plan view, an input signal line corresponding to the second display panel is provided on an outer side of an input signal line corresponding to the first display panel.

3. The display device as set forth in claim 1, wherein:
power lines corresponding to respective two adjacent display panels among the plurality of display panels are provided between (i) a plurality of input signal lines corresponding to one of the two adjacent display panels and (ii) a plurality of input signal lines corresponding to the other of the two adjacent display panels.

4. A display device as set forth in claim 1, further comprising counter electrodes which are separately provided for the respective plurality of display panels.

5. The display device as set forth in claim 4, wherein:
different electric potentials are supplied to the respective counter electrodes.

6. The display device as set forth in claim 4, wherein:
the plurality of display panels are constituted by (i) a display panel having a counter electrode to which a DC voltage is supplied and (ii) a display panel having a counter electrode to which an AC voltage is supplied.

7. A display device as set forth in claim 1, further comprising a counter electrode which is shared by the plurality of display panels and to which a constant electric potential is supplied.

8. The display device as set forth in claim 1, wherein:
the number of the plurality of data signal lines varies among the plurality of display panels; and
the number of the plurality of scanning signal lines varies among the plurality of display panels.
